(19) United States
(12) Patent Application Publication
(10) Pub. No.: US 2010/0156446 A1
(43) Pub. Date: Jun. 24, 2010

(54) METHOD OF INSPECTING A SUBSTRATE

(75) Inventors: Chun-Yong KIM, Seoul (KR); Mi-Ra Park, Suwon-si (KR); Yun-Jung Jee, Seongnam-si (KR); Chung-Sam Jun, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/641,918

(22) Filed: Dec. 18, 2009

(30) Foreign Application Priority Data
Dec. 22, 2008 (KR) 2008-130837

(51) Int. Cl. G01R 31/02; G01R 31/26

(52) U.S. Cl. 324/754; 324/765

(57) ABSTRACT

A method of inspecting a substrate includes measuring a first current flowing between a first region and a second region of the substrate using a first probe. A second current flowing between the first region and the second region of the substrate may be measured using a second probe including a material different from that of the first probe. By comparing the first and second currents, it can be determined whether there is a change in a physical composition of the substrate and a change in a physical configuration of the substrate between the first region and the second region. Thus, when the current change is induced by the change in a physical configuration of the substrate, a determination error that the contaminants on the semiconductor substrate may exist based on the current change may be prevented.

### CROSS-REFERENCE TO RELATED APPLICATIONS

This application claims priority under 35 USC §119 to Korean Patent Application No. 2008-130837, filed on Dec. 22, 2008 in the Korean Intellectual Property Office (KIPO), the contents of which are herein incorporated by reference in their entirety.

### BACKGROUND

1. Field of the Invention

Example embodiments relate to a method of inspecting a substrate and an apparatus to perform the same. More particularly, example embodiments relate to a method of inspecting a semiconductor substrate using a non-contact probe, and an apparatus to perform the method.

2. Description of the Related Art

Generally, semiconductor devices may be manufactured by performing a plurality of processes on a semiconductor substrate. Byproducts generated after the processes may remain on the semiconductor substrate. The byproducts may act as contaminants that may negatively affect the semiconductor substrate. Thus, it may be necessary to perform a process to detect the contaminants on the semiconductor substrate.

A probe may be used to detect the contaminants. The probe may be either a contact probe configured to directly contact the semiconductor substrate or a non-contact probe configured to not make contact with the semiconductor substrate. When a contact probe is used, it may damage the semiconductor substrate. Thus, a non-contact probe may be used to prevent damage to the substrate. The non-contact probe may be spaced apart from the semiconductor substrate. The non-contact probe may measure a current change that flows along a surface of the semiconductor substrate to detect the contaminants on the semiconductor substrate.

The current change may be induced by a change in a physical configuration of the substrate in the configuration, shape, or structure of the semiconductor substrate as well as by the contaminants. For example, when a step or a change in a surface level exists between a first region and a second region of the semiconductor substrate, a current change measured using the non-contact probe may be generated.

However, when the current change is measured using the conventional non-contact probe, it may not be determined whether the current change is induced by a change in physical composition of the substrate, such as by the presence of contaminants on or in the substrate, or whether the current change is induced by a change in the physical features or change in a physical configuration of the substrate of the substrate.

### SUMMARY

Example embodiments provide a method of inspecting a substrate that may be accurately discriminate between a current change induced by a change in the physical composition of a substrate and a current change induced by a change in a physical configuration of the substrate.

Example embodiments also provide an apparatus to perform the above-mentioned method.

Additional aspects and utilities of the present general inventive concept will be set forth in part in the description which follows and, in part, will be obvious from the description, or may be learned by practice of the general inventive concept.

Features and/or utilities of the present general inventive concept may be realized by a method of inspecting a substrate. In the method of inspecting the substrate, a first current flowing between a first region and a second region of the substrate may be measured using a first probe. A second current flowing between the first region and the second region of the substrate may be measured using a second probe including a material different from that of the first probe. Whether a change in a physical composition of the substrate and a change in a physical configuration of the substrate between the first region and the second region exist may be determined based on the first current and the second current.

Measuring the first current and the second current may include using the first probe spaced apart from the substrate by a first distance and the second probe spaced apart from the substrate by a second distance substantially the same as the first distance.

Determining whether the change in a physical composition of the substrate and the change in a physical configuration of the substrate exists may include deciding that there is neither a change in a physical composition of the substrate nor a change in a physical configuration of the substrate when the first current and the second current may be zero, deciding that only the change in a physical composition of the substrate exists between the first region and the second region when the first current is substantially the same as the second current, and deciding that only a change in a physical configuration of the substrate exists or that both a change in a physical composition of the substrate and a change in a physical configuration of the substrate exist between the first region and the second region when the first current is different from the second current.

The method may further include measuring a third current flowing between the first region and the second region using a third probe spaced apart from the substrate by a third distance greater than the first distance.

Additional features and/or utilities of the present general inventive concept may be realized by an apparatus to inspect a substrate. The apparatus to inspect the substrate may include a first probe and a second probe. The first probe may be located over the substrate to measure a first current flowing between a first region and a second region of the substrate. The second probe may be located over the substrate to measure a second current flowing between the first region and the second region. The second probe may include a material different from that of the first probe.

The first probe may be spaced apart from the substrate by a first distance and the second probe may be spaced apart from the substrate by a second distance substantially the same as the first distance.

The first probe may include stainless steel and the second probe may include tungsten.

The apparatus may further include a third probe to measure a third current that may flow between the first region and the second region. The third probe may be spaced apart from the substrate by a third distance greater than the first distance. Further, the third probe may include a material substantially the same as that of the first probe.

According to example embodiments, the first current and the second current flowing between the first region and the second region of the substrate may be measured using the first probe and the second probe that may be composed of different materials. Thus, a change in or difference in the first and second currents may indicate whether the currents are a result of a difference in a physical composition of the substrate or a difference in a physical configuration of the substrate. As a result, when the current change is induced by the change in a physical configuration of the substrate, a determination error that the contaminants on the semiconductor substrate may exist based on the current change may be prevented.

Features and/or utilities of the present general inventive concept may also be realized by a substrate testing apparatus including a first probe positioned a first distance over a substrate to measure a first current flowing from a first portion of the substrate to a second portion of the substrate and a second probe positioned a second distance over the substrate to measure a second current flowing between the first portion and the second portion of the substrate.

The first distance is the same as the second distance. The testing apparatus may further include a third probe positioned a third distance over the substrate to measure a third current flowing between the first portion and the second portion, and the third distance may be greater than the first distance.

The testing apparatus may further include a comparison unit to receive outputs from the first probe and the second probe and to determine whether an output of the first probe is substantially the same as an output of the second probe.

The first probe may include a material different than that of the second probe.

Features and/or utilities of the present general inventive concept may also be realized by a method of analyzing a substrate including detecting a first current flowing between a first portion of a substrate and a second portion of the substrate, detecting a second current flowing between the first portion of the substrate and the second portion of the substrate, and comparing the first current to the second current to determine at least one of a physical composition of the substrate and a physical configuration of the substrate.

Comparing the first current to the second current may include determining whether a first current and a second current exist and when the first current and the second current exist, determining whether the first current and the second current are substantially the same.

The method may further include detecting a third current flowing between the first portion and the second portion of the substrate. The first current may be detected by a first probe positioned a first distance from the substrate, the second current may be detected by a second probe positioned the first distance from the substrate, and the third current may be detected by a third probe positioned a second distance from the substrate, the second distance being greater than the first distance.

Detecting the first and second currents may include moving first and second probes, respectively, in a horizontal direction with respect to the substrate across a surface of the substrate.

Features and/or utilities of the present general inventive concept may also be realized by a method of analyzing a substrate including positioning a plurality of current-sensing probes over a first region of a substrate, such that a first probe is closer to a boundary of the first region than a second probe, moving the current-sensing probes relative to the substrate, and detecting a current with each of the current-detecting probes to determine when a material composition of the first region is different than a material composition in a second region adjacent to the first region.

### BRIEF DESCRIPTION OF THE DRAWINGS

The above and/or other aspects of the present general inventive concept will become apparent and more readily appreciated from the following description of the exemplary embodiments, taken in conjunction with the accompanying drawings, in which:

FIG. 1 is a perspective view illustrating an apparatus for inspecting a substrate in accordance with some example embodiments;

FIG. 2 is a perspective view illustrating an apparatus for inspecting a substrate in accordance with some example embodiments;

FIG. 3 is a flow chart illustrating a method of inspecting a substrate using the apparatus in FIG. 1;

FIG. 4 is a perspective view illustrating a process for inspecting a substrate having only a change in a physical composition of the substrate;

FIG. 5 is a perspective view illustrating a process for inspecting a substrate having only a change in a physical configuration of the substrate; and

FIG. 6 is a block diagram of a substrate test apparatus according to an embodiment of the present general inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, when the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

FIG. 1 is a perspective view illustrating an apparatus to inspect a substrate in accordance with some example embodiments.

Referring to FIG. 1, an apparatus 100 of this example embodiment may include a first probe 110 and a second probe 120. The first probe 110 and the second probe 120 may be connected in parallel with a power supply 140.

The first probe 110 may be located over a semiconductor substrate S. In some example embodiments, the first probe 110 may be spaced apart from an upper surface of the semiconductor substrate S by a first distance D1. The first probe 110 may include a first material, such as stainless steel. The first probe 110 may have a cross-sectional area A.

The first probe 110 may move in a first horizontal direction 101 over the semiconductor substrate S to measure a first current J1 flowing along the upper surface of the semiconductor substrate S. In some example embodiments, the semiconductor substrate S may have a first region R1 and a second region R2. The first probe 110 may be moved from the first region R1 to the second region R2 to measure the first current J1 flowing between the first region R1 and the second region R2. The first current J1 may be obtained from a following formula 1.

J1=(φR1−φ1)[Aε₀ε/(D1−Aε₀ε/(D1−x)]+(φR2−φR1)(Aε₀ε/D1) Formula 1

In Formula 1, φR1 represents a work function of the first region R1, φ1 indicates a work function of the first probe 110, ε₀ represent a vacuum permittivity, ε indicates a permittivity of a material between the first probe 110 and the semiconductor substrate S, x represents a step between the first region R1 and the second region R2, and φR2 indicates a work function of the second region R2.

When the step x does not exist between the first region R1 and the second region R2 and the work function φR1 of the first region R1 is substantially the same as the work function φR2 of the second region R2, the first current J1 is zero. That is, when a change in a physical composition of the substrate and a change in a physical configuration of the substrate between the first region R1 and the second region R2 do not exist, the first current J1 does not flow between the first region R1 and the second region R2.

In contrast, when a step x exists between the first region R1 and the second region R2 or the work function φR1 of the first region R1 is different from the work function φR2 of the second region R2, the first current J1 flows between the first region R1 and the second region R2. The first probe 110 may measure the first current J1 to determine whether the change in a physical composition of the substrate or the change in a physical configuration of the substrate between the first region R1 and the second region R2 exists.

The second probe 120 may be arranged over the semiconductor substrate S. The second probe 120 may be spaced apart from the upper surface of the semiconductor substrate S by a second distance D2. The second distance D2 may be substantially the same as the first distance D1. That is, the first probe 110 and the second probe 120 may be spaced apart from the upper surface of the semiconductor substrate S by substantially the same distance. The second probe 120 may include a second material different from the first material. For example, the second probe 120 may include tungsten. The second probe 120 may have a cross-sectional area A substantially the same as that of the first probe 110.

The second probe 120 may move in a horizontal direction 101 direction over the semiconductor substrate S to measure a second current J2 flowing along the upper surface of the semiconductor substrate S. The second probe 120 may measure the second current J2 flowing between the first region R1 and the second region R2. The second current J2 may be obtained from a following formula 2.

J2=(φR1−φ2)[Aε₀ε/(D2−Aε₀ε/(D2−x)]+(φR2−φR1)(Aε₀ε/D2) Formula 2

In Formula 2, φ2 indicates a work function of the second probe 120.

When a step or change in physical configuration of the substrate does not exist between the first region R1 and the second region R2 and the work function φR1 of the first region R1 is substantially the same as the work function φR2 of the second region R2, the second current J2 is zero. That is, when the change in a physical composition of the substrate and the change in a physical configuration of the substrate between the first region R1 and the second region R2 does not exist, the second current J2 does not flow between the first region R1 and the second region R2.

In contrast, when a step x or change in physical configuration exists between the first region R1 and the second region R2 or when the work function φR1 of the first region R1 is different from the work function φR2 of the second region R2, the second current J2 may flow between the first region R1 and the second region R2. The second probe 120 may measure the second current J2 to determine whether the change in a physical composition of the substrate or the change in a physical configuration of the substrate between the first region R1 and the second region R2 exists.

In Formulas 1 and 2, an identification between the first current J1 and the second current J2 may mean that only the change in a physical composition of the substrate such as a material change may exist between the first region R1 and the second region R2 and the change in a physical configuration of the substrate such as the step x may not exist between the first region R1 and the second region R2. In contrast, a difference between the first current J1 and the second current J2 may mean that only the change in a physical configuration of the substrate may exist between the first region R1 and the second region R2 or all of the change in a physical composition of the substrate and the change in a physical configuration of the substrate may exist between the first region R1 and the second region R2. That is, the difference between the first current J1 and the second current J2 may mean that the change in a physical configuration of the substrate may exist at least between the first region R1 and the second region R2.

According to this example embodiment, the currents flowing between the first region and the second region may be measured using the two probes including different materials. Thus, whether the current change may be induced by the change in a physical composition of the substrate or the change in a physical configuration of the substrate may be accurately determined.

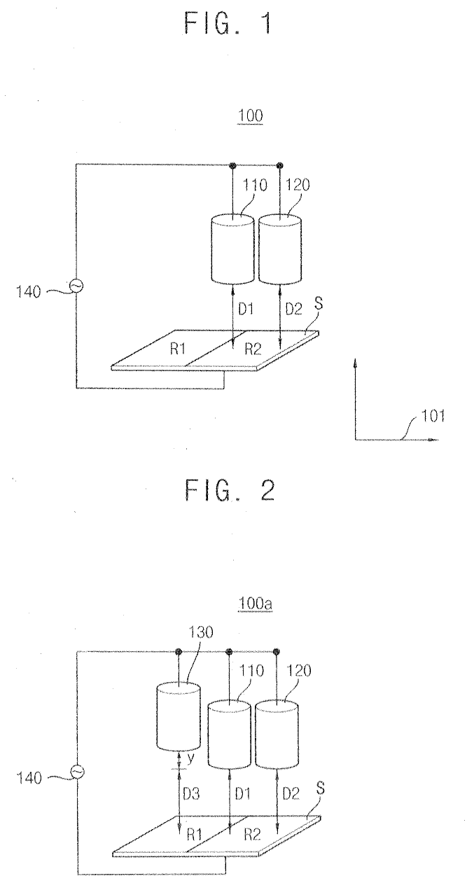

FIG. 2 is a perspective view illustrating an apparatus to inspect a substrate in accordance with some example embodiments.

Referring to FIG. 2, an apparatus 100a of this example embodiment may include elements substantially the same as those of the apparatus 100 in FIG. 1 except that the apparatus of this example embodiment may further include a third probe 130. Thus, the same reference numerals refer to the same elements and any further descriptions with respect to the same elements are omitted herein for brevity.

The third probe 130 may be arranged spaced apart from the upper surface of the semiconductor substrate S by a third distance D3 (D1+y). The third probe 130 may include a third material substantially the same as the first material. The third probe 130 may have a cross-sectional area A substantially the same as that of the first probe 110.

The third probe 130 may be moved in the horizontal direction 101 over the semiconductor substrate S to measure a third current J3 flowing along the upper surface of the semiconductor substrate S. In some example embodiments, the third probe 130 may measure the third current J3 flowing between the first region R1 and the second region R2. The third current J3 may be obtained from a following formula 3.

J3=(φR1−φ3)[Aε₀ε/(D3+y)−Aε₀ε/(D3+y−x)]+(φR2−φR1)(Aε₀ε/(D3+y)) Formula 3

In Formula 3, φ3 indicates a work function of the third probe 130, and y represent a height difference between the first probe 110 and the third probe 130.

When a step or change in physical configuration of the substrate does not exist between the first region R1 and the second region R2 and the work function φR1 of the first region R1 are substantially the same as the work function φR2 of the second region R2, the third current J3 is zero. That is, when there is no change in a physical composition of the substrate and no change in a physical configuration of the substrate between the first region R1 and the second region R2, the third current J3 does not flow between the first region R1 and the second region R2.

In contrast, when a step x or change in a physical configuration of the substrate exists between the first region R1 and the second region R2, or the work function φR1 of the first region R1 is different from the work function φR2 of the second region R2, the third current J3 may flow between the first region R1 and the second region R2. The third probe 130 may measure the third current J3 to determine whether a change in a physical composition of the substrate exists or a change in a physical configuration of the substrate exists between the first region R1 and the second region R2.

In Formulas 1 and 3, when the first current J1 and the third current J3 are represented as a function having only variables of the work functions, this may mean that only the change in a physical composition of the substrate such as a material change exists between the first region R1 and the second region R2 and the change in a physical configuration of the substrate such as a step x does not exist between the first region R1 and the second region R2. In contrast, when the first current J1 and the third current J3 are represented as a function having only variables of the height difference y, this may mean that only the change in a physical configuration of the substrate exists between the first region R1 and the second region R2 or that both a change in a physical composition of the substrate and a change in a physical configuration of the substrate exist between the first region R1 and the second region R2.

The change in a physical composition of the substrate and the change in a physical configuration of the substrate of the semiconductor substrate S may be clearly discriminated from each other using the first probe 110 and the second probe 120. Thus, the third probe 130 may be additionally used in the apparatus 100a.

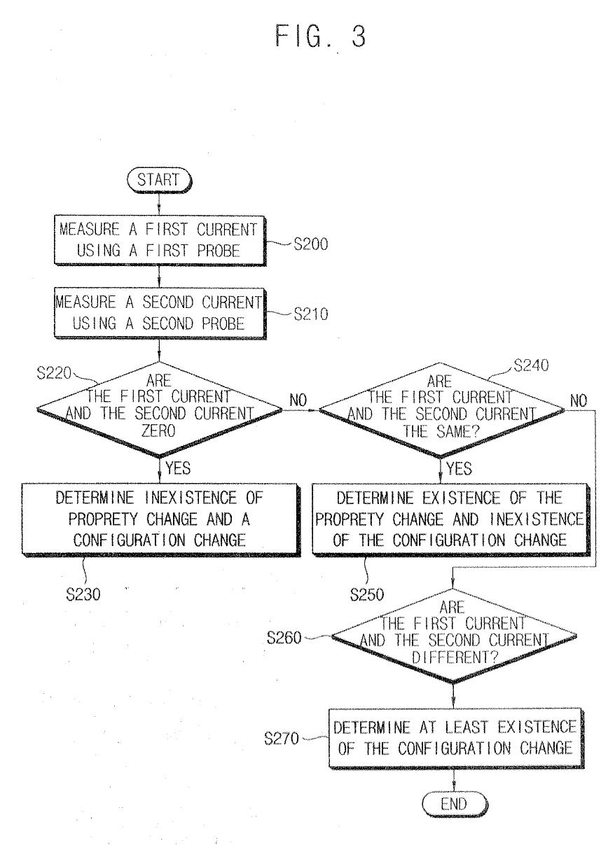

FIG. 3 is a flow chart illustrating a method of inspecting a substrate using the apparatus in FIG. 1.

Referring to FIGS. 1 and 3, in operation S200, the first probe 110 may measure the first current J1 flowing between the first region R1 and the second region R2 of the semiconductor substrate S. In some example embodiments, the first probe 110 may be moved over the semiconductor substrate S. Alternatively, the semiconductor substrate S may be moved and the first probe 110 may remain stationary.

In operation S210, the second probe 120 may measure the second current J2 flowing between the first region R1 and the second region R2 of the semiconductor substrate S. In some example embodiments, the second probe 120 may include the second material different from the first material of the first probe 110. The first probe 110 and the second probe 120 may be separated from the upper surface of the semiconductor substrate S by substantially the same distance. The first probe 110 and the second probe 120 may have substantially the same cross-sectional area.

In operation S220, it may be determined whether the first current J1 and the second current J2 are zero, and when the first current J1 and the second current J2 are zero, it may be determined in operation S230 that there is no change in a physical composition of the substrate and a physical configuration of the substrate between the first region R1 and the second region R2.

In some example embodiments, the zero values of the first current J1 and the second current J2 may mean that the currents are not flowing through the semiconductor substrate S. Thus, the first region R1 and the second region R2 of the semiconductor substrate S may include substantially the same material. Further, there may be no step or change in physical configuration between the first region R1 and the second region R2.

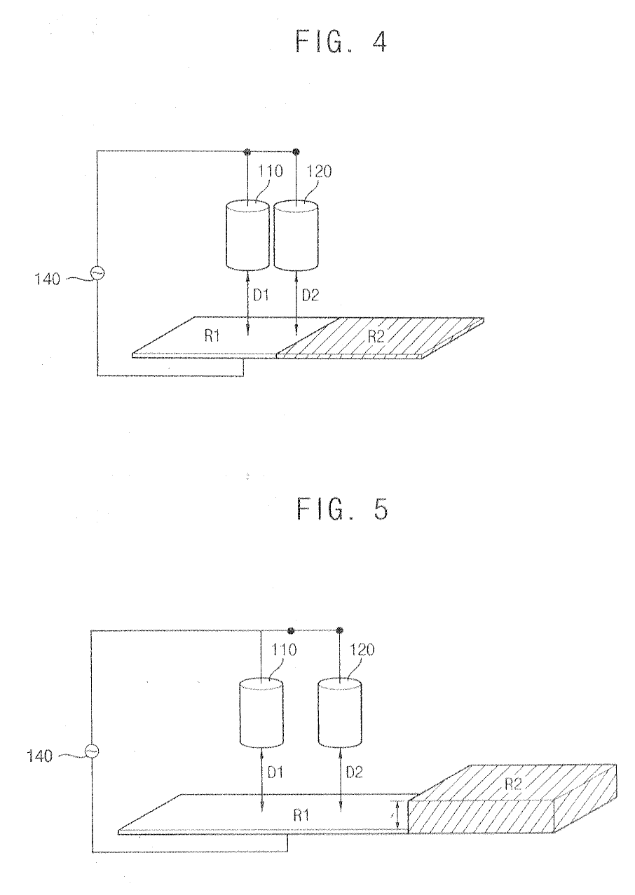

In operation S240, as shown in FIG. 4, it may be determined whether the first current J1 is substantially the same as the second current J2. When so, it may be determined in operation S250 that there is a change in a physical composition of the substrate and that there is no change in a physical configuration of the substrate between the first region R1 and the second region R2.

In some example embodiments, in Formulas 1 and 2, variables may be the step x and the work functions. Alternatively, the work function φ1 of the first region R1 and the work function φ2 of the second region R2 may be constants. Thus, when no step x exists between the first region R1 and the second region R2, the first current J1 may be substantially the same as the second current J2. As a result, determining that a first current J1 and a second current J2 exist and that the first current J1 and the second current J2 are the same means that there is a change in a physical composition of the substrate, i.e., a material change, between the first region R1 and the second region R2.

In operation S260, as shown in FIG. 5, it may be determined whether the first current J1 is different from the second current J2. When the first current J1 is different from the second current J2, it may be determined in operation S270 that there is a change in a physical configuration of the substrate and that there may or may not be a change in a physical composition of the substrate between the first region R1 and the second region R2. Therefore, the difference between the first current J1 and the second current J2 means that at least a change in a physical configuration of the substrate exists between the first region R1 and the second region R2.

In some example embodiments, in Formulas 1 and 2, because the work function φ1 of the first region R1 and the work function φ2 of the second region R2 may be constants, the step x may be the only variable. Thus, when there is a difference between the first current J1 and the second current J2, it may mean that there is a change in a physical configuration of the substrate. i.e., that a step exists between the first region R1 and the second region R2.

Additionally, whether the current change may be induced by the change in a physical composition of the substrate or the change in a physical configuration of the substrate may be accurately determined using the third probe 130.

In some example embodiments, the substrate may include the semiconductor substrate. Alternatively, the method and the apparatuses may be used for inspecting other substrates such as an LCD substrate.

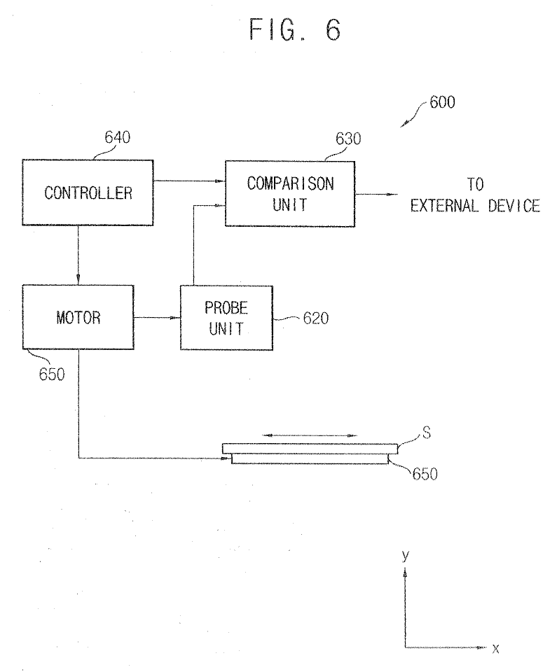

FIG. 6 illustrates a block diagram of a substrate analysis or test apparatus 600 according to an embodiment of the present general inventive concept. The apparatus 600 may include a mount 610 to hold the substrate S. A probe unit 620 may be positioned a predetermined distance above the substrate S to detect a current flowing on the substrate, as disclosed above. The probe unit 620 may include multiple probes, or there may be multiple probe units 620. A comparison unit 630 receives an output from the probe unit 620 to determine whether one or more currents are detected by the probe unit 620 and whether the one or more currents have a same magnitude. The comparison unit 630 may output a signal to an external device, indicating a result of the comparison. For example, when multiple currents of different levels are detected by the probe unit 620, the comparison unit 630 may output a signal indicating that a physical composition of the substrate S changes between a first portion of the substrate and a second portion of the substrate.

The apparatus 600 may include a controller to control operation of the comparison unit 630, the probe unit 620, and or the mount 610. For example, the controller 640 may control a motor 650 to move the probe unit 620 relative to the mount 610 and the substrate S in the direction x. The motor 650 may move either the probe unit 620, the mount 610, or both. The motor 650 may also move the probe unit 620 and mount 610 in the vertical direction y relative to each other. The motor 650 may be any appropriate motor, such as a servo-motor or a step motor. The controller 640 may also control output signals from the comparison unit 630 to external devices.

The controller 640 may be a processor, logic, or any combination of a processor, logic, and memory. The controller 640 may be integral with the comparison unit 630, or they may be distinct devices or semiconductor chips. The controller 640 and comparison unit 630 may also be embodied by computer-readable code stored in memory and executed by a processor.

According to some example embodiments, the first current and the second current flowing between the first region and the second region of the substrate may be measured using the first probe and the second probe including different materials. Thus, it may be accurately determined whether a current change of the first current and the second current is induced by a change in a physical composition of the substrate or by a change in a physical configuration of the substrate. As a result, determination errors that contaminants exist on the semiconductor substrate may be prevented.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

Although a few embodiments of the present general inventive concept have been shown and described, it would be appreciated by those skilled in the art that changes may be made in these embodiments without departing from the principles and spirit of the general inventive concept, the scope of which is defined in the claims and their equivalents.

1. A method of inspecting a substrate, the method comprising:
measuring a first current flowing between a first region and a second region of the substrate using a first probe;
measuring a second current flowing between the first region and the second region using a second probe; and
determining whether a change in a physical composition of the substrate and a change in a physical configuration of the substrate exist between the first region and the second region based on the first current and the second current.

2. The method of claim 1, wherein the first probe and the second probe are spaced apart from the substrate by substantially the same distance.

3. The method of claim 1, wherein determining whether the change in a physical composition of the substrate and the change in a physical configuration of the substrate exist comprises:
deciding that the change in a physical composition of the substrate and the change in a physical configuration of the substrate do not exist between the first region and the second region when the first current and the second current are zero;
deciding that only the change in a physical composition of the substrate exists between the first region and the second region when the first current is substantially the same as the second current; and
deciding that the change in a physical configuration of the substrate exists between the first region and the second region when the first current is different from the second current.

4. The method of claim 1, further comprising measuring a third current flowing between the first region and the second region using a third probe that is spaced apart from the substrate by a distance greater than the distance between the first probe and the substrate.

5-15. (canceled)

16. A method of analyzing a substrate, the method comprising:
detecting a first current flowing between a first portion of a substrate and a second portion of the substrate;
detecting a second current flowing between the first portion of the substrate and the second portion of the substrate; and
comparing the first current to the second current to determine at least one of a physical composition of the substrate and a physical configuration of the substrate.

17. The method according to claim 16, wherein comparing the first current to the second current comprises:
determining whether a first current and a second current exist; and
when the first current and the second current exist, determining whether the first current and the second current are substantially the same.

18. The method according to claim 16, further comprising:
detecting a third current flowing between the first portion and the second portion of the substrate,
wherein the first current is detected by a first probe positioned a first distance from the substrate,
the second current is detected by a second probe positioned the first distance from the substrate, and
the third current is detected by a third probe positioned a second distance from the substrate, the second distance being greater than the first distance.

19. The method according to claim 16, wherein detecting the first and second currents comprises moving first and second probes, respectively, in a horizontal direction with respect to the substrate across a surface of the substrate.
